(19) United States
(12) Patent Application Publication
(10) Pub. No.: US 2026/0344543 A1
(43) Pub. Date: Oct. 29, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Yasuo FUJITA, Fukuoka (JP)

(73) Assignee: Mitsubishi Electric Corporation, Tokyo (JP)

(21) Appl. No.: 19/531,704

(22) Filed: Feb. 6, 2026

(30) Foreign Application Priority Data
Apr. 24, 2025 (JP) 2025-072328

(51) Int. Cl. H10W 90/00; H10W 70/04; H10W 70/40; H10W 74/01; H10W 74/10; H10W 90/10

(52) U.S. Cl. CPC H10W 90/753; H10W 70/411; H10W 74/016; H10W 74/114; H10W 90/10; H10W 90/756; H10W 90/811; H10W 70/048

(57) ABSTRACT

Contact of a deformed wire with a frame is prevented more reliably in a semiconductor device. A semiconductor device includes a frame including a first die pad portion including a first semiconductor element, a metal wire connected to the first semiconductor element, and sealing resin sealing a part of the frame, the first semiconductor element, and the metal wire. The first die pad portion includes a first non-protruding portion as a part which does not protrude from the first semiconductor element in a region in which the metal wire passes through in a plan view.

### BACKGROUND

### Technical Field

The present disclosure relates to a semiconductor device and a method of manufacturing the semiconductor device.

### Description of the Background Art

For example, a transfer-molded semiconductor device is widely used for a semiconductor device for controlling electrical power. Generally, the transfer-molded semiconductor device has a configuration that a power control semiconductor element such as a metal oxide semiconductor field effect transistor (MOSFET) and an insulated gate bipolar transistor (IGBT) and a control semiconductor element (control integrated circuit (IC)) controlling the semiconductor element are electrically connected by a wire, and are sealed with sealing resin together with a frame including them. In a manufacturing process thereof, the frame including the power control semiconductor element and the control semiconductor element connected by the wire is disposed in a mold, and resin is flowed in the mold to form the sealing resin. At that time, the wire is deformed by the resin flowing in the mold in some cases. When the deformed wire has contact with the frame, short circuit of a circuit occurs and the semiconductor device is not normally operated.

Japanese Patent Application Laid-Open No. 11-126864 described hereinafter proposes a technique of providing a notch in an end part of the frame located below the wire to prevent the wire from having contact with the frame even if sag occurs in the wire.

### SUMMARY

In the technique of Japanese Patent Application Laid-Open No. 11-126864, the notch provided to the end part of the frame does not reach the semiconductor element, and an upper surface of the frame is exposed between the semiconductor element and the notch. Thus, there is a possibility that the wire sagging from an upper surface of the semiconductor element has contact with the upper surface of the frame exposed between the semiconductor element and the notch.

An object of the present disclosure is to provide a semiconductor device capable of preventing a deformed wire from having contact with a frame more reliably.

A semiconductor device according to the present disclosure includes at least one frame including a first die pad portion including a first semiconductor element, a metal wire connected to the first semiconductor element, and sealing resin sealing a part of the frame, the first semiconductor element, and the metal wire. The first die pad portion includes a first non-protruding portion as a part which does not protrude from the first semiconductor element in a region in which the metal wire passes through in a plan view.

According to the semiconductor device in the present disclosure, contact of a deformed wire with a frame can be prevented more reliably.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a frame of a semiconductor device according to an embodiment 1.

FIG. 2 is a plan view near a first die pad portion and a second die pad portion in the semiconductor device according to the embodiment 1.

FIG. 3 is a cross-sectional view of the first die pad portion and the second die pad portion in the semiconductor device according to the embodiment 1.

FIG. 4 is a diagram illustrating a state where sag occurs in a metal wire in a conventional semiconductor device.

FIG. 5 is a diagram illustrating a state where sag occurs in a metal wire in the semiconductor device according to the embodiment 1.

FIG. 6 is a plan view near a first die pad portion and a second die pad portion in a modification example of the semiconductor device according to the embodiment 1.

FIG. 7 is a cross-sectional view of a first die pad portion and a second die pad portion in a modification example of the semiconductor device according to the embodiment 1.

FIG. 8 is a cross-sectional view of a first die pad portion and a second die pad portion in a semiconductor device according to an embodiment 2.

FIG. 9 is a cross-sectional view of a first die pad portion and a second die pad portion in a modification example of the semiconductor device according to the embodiment 2.

FIG. 10 is a cross-sectional view of a first die pad portion and a second die pad portion in a modification example of the semiconductor device according to the embodiment 2.

FIG. 11 is a diagram for explaining a method of manufacturing a semiconductor device according to an embodiment 3.

### DESCRIPTION OF THE PREFERRED EMBODIMENTS

### Embodiment 1

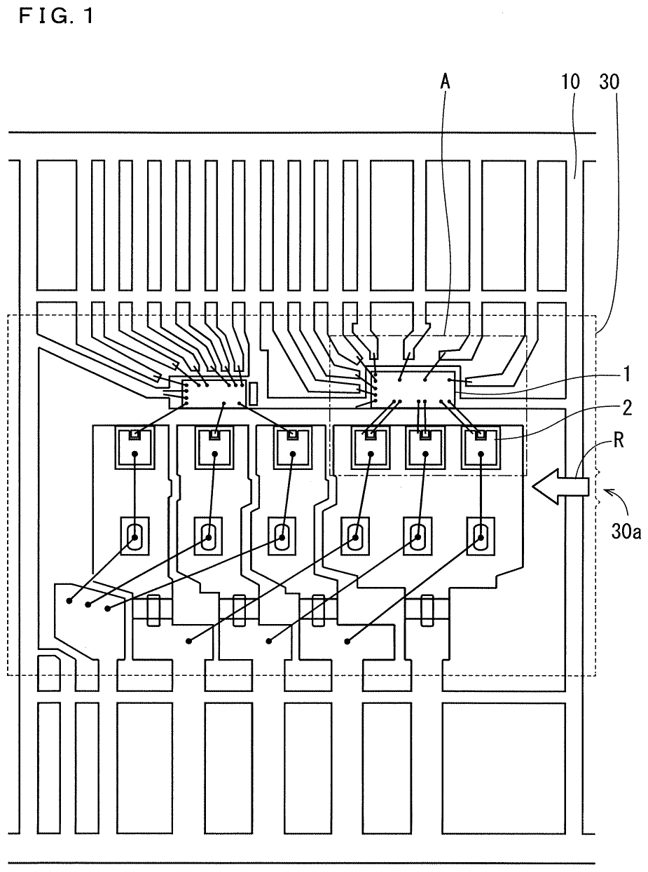

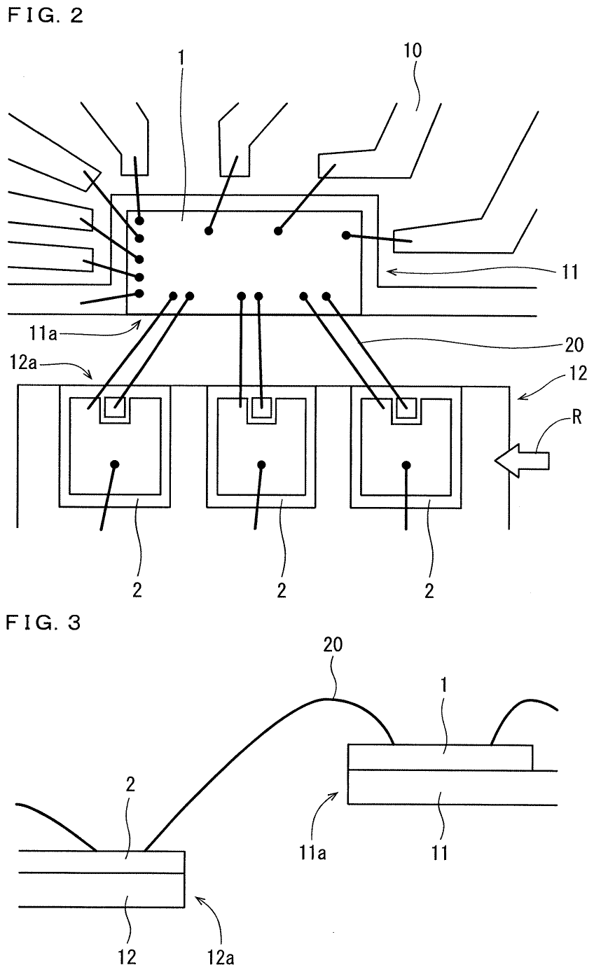

FIG. 1 is a plan view of a frame 10 of a semiconductor device according to an embodiment 1. FIG. 2 is a plan view of a main portion of the semiconductor device according to the embodiment 1, and is an enlarged view of a part of a region A illustrated in FIG. 1.

As illustrated in FIG. 1 and FIG. 2, the semiconductor device includes a first semiconductor element 1 as a control IC and a second semiconductor element 2 as a power control semiconductor element (for example, a MOSFET or an IGBT) controlled by the first semiconductor element 1. As illustrated in FIG. 2, the first semiconductor element 1 is mounted to a first die pad portion 11 of a frame 10, and the second semiconductor element 2 is mounted to a second die pad portion 12 of the frame 10. The semiconductor device includes a plurality of metal wires 20 connected to an electrode provided to upper surfaces of the first semiconductor element 1 and the second semiconductor element 2. Some of the plurality of metal wires 20 connects between the first semiconductor element 1 and the second semiconductor element 2, and the other some thereof connects between the first semiconductor element 1 and the frame 10 or between the second semiconductor element 2 and the other semiconductor element (for example, a free wheeling diode (FWD)). The second semiconductor element 2 also includes an electrode in a bottom surface, and the electrode in the bottom surface of the second semiconductor element 2 is electrically connected to the frame 10 (the second die pad portion 12) via a bonding material such as solder.

A part of the frame 10 including the first die pad portion 11 and the second die pad portion 12, the first semiconductor element 1, the second semiconductor element 2, and the metal wire 20 are sealed by sealing region 30 shown by a broken line in FIG. 1. A part of the frame 10 protruding from the sealing resin 30 serves as an external connection terminal. FIG. 1 illustrates the frame 10 before being sealed by the sealing resin 30, and parts serving as the external connection terminals are connected to each other. After the sealing resin 30 is formed, the external connection terminals are separated from each other.

Herein, the sealing resin 30 is formed by locating the frame 10 to which the first semiconductor element 1, the second semiconductor element 2, and the metal wire 20 are mounted in a mold for molding the sealing resin 30 and injecting resin from a resin injection inlet of the mold. Thus, a resin injection mark 30a as a mark of a resin injection inlet of the mold of the sealing resin 30 remains in a surface of the sealing resin 30 (generally a side surface) as illustrated in FIG. 1. In such a case, a direction R (referred to as “a resin flowing direction R” hereinafter) in which the resin flowing from the resin injection inlet of the mold flows in forming the sealing resin 30 can be estimated as a direction perpendicular to a side including the resin injection mark 30a of the sealing resin 30. A shape of the resin injection mark 30a may be a convex shape protruding from a surface of the sealing resin 30 or a concave shape depressed from the surface of the sealing resin 30 depending on a way of detaching the sealing resin 30 from the mold.

The resin injection mark 30a may not remain in the surface of the sealing resin 30. In this case, it is difficult to estimate the resin flowing direction R from an outer appearance of the sealing resin 30. However, in consideration of filling properties of the resin in the mold, a position of the resin injection inlet of the mold is generally disposed so that the resin flowing direction R is a longitudinal direction of the sealing resin 30. Thus, in a case where the resin injection mark 30a does not remain in the surface of the sealing resin 30, when the sealing resin 30 has a rectangular shape in a plan view as illustrated in FIG. 1, the resin flowing direction R can be estimated as the longitudinal direction of the sealing resin 30.

In the semiconductor device according to the embodiment 1, the first die pad portion 11 of the frame 10 includes a first non-protruding portion 11a as a part which does not protrude from the first semiconductor element 1 in the region in which the metal wire 20 passes through in a plan view. In the similar manner, the second die pad portion 12 of the frame 10 includes a second non-protruding portion 12a as a part which does not protrude from the second semiconductor element 2 in the region in which the metal wire 20 passes through in a plan view.

The first non-protruding portion 11a or the second non-protruding portion 12a needs not be provided to all of the metal wires 20, but it is sufficient that it is provided to at least some metal wire 20. In the present embodiment, the first non-protruding portion 11a is provided to a side parallel to the resin flowing direction R (a side parallel to the longitudinal direction of the sealing resin 30) of the first die pad portion 11 in a plan view, and the second non-protruding portion 12a is provided to a side parallel to the resin flowing direction R of the second die pad portion 12 in a plan view. Since the metal wire 20 passing across the side parallel to the resin flowing direction R is pressed by the resin from a lateral side and significantly deformed (deformation of the metal wire 20 extending along the resin flowing direction R is small), it is effective to provide the first non-protruding portion 11a or the second non-protruding portion 12a to the side parallel to the resin flowing direction R.

FIG. 3 is a cross-sectional view of the first die pad portion 11 including the first non-protruding portion 11a and the second die pad portion 12 including the second non-protruding portion 12a. An end part of the first die pad portion 11 in the first non-protruding portion 11a does not protrude more than an end part of the first semiconductor element 1, and an end part of the second die pad portion 12 in the second non-protruding portion 12a does not protrude more than and end part of the second semiconductor element 2. Thus, the upper surface of the frame 10 is not exposed in the first non-protruding portion 11a and the second non-protruding portion 12a.

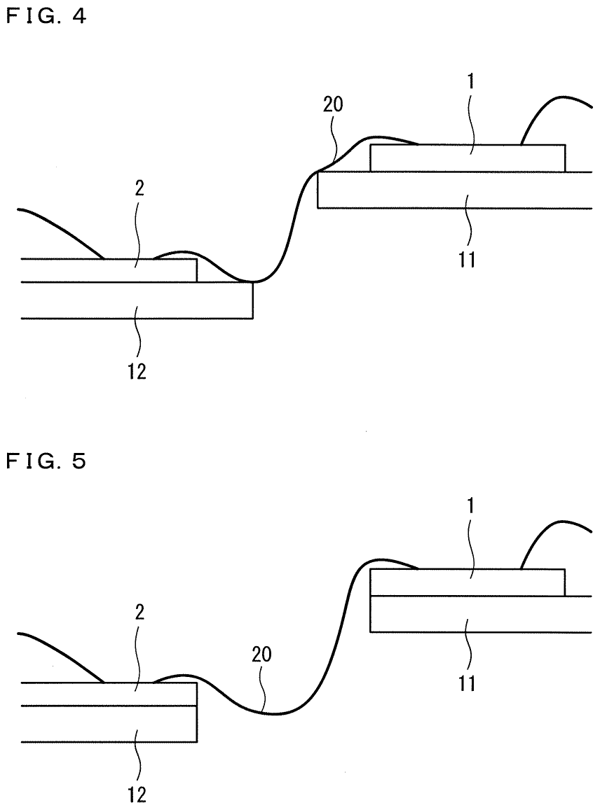

If the end part of the first die pad portion 11 protrudes more than the end part of the first semiconductor element 1 and the end part of the second die pad portion 12 protrudes more than the end part of the second semiconductor element 2, there is a possibility that the metal wire 20 is deformed by flow of the resin in forming the sealing resin 30 and has contact with the frame 10 when sag occurs in the metal wire 20 as illustrated in FIG. 4. In contrast, in the semiconductor device according to the present embodiment, the end part of the first die pad portion 11 in the first non-protruding portion 11a does not protrude more than the end part of the first semiconductor element 1, and the end part of the second die pad portion 12 in the second non-protruding portion 12a does not protrude more than the end part of the second semiconductor element 2. Thus, even when sag occurs in the metal wire 20 as illustrated in FIG. 5, contact of the metal wire 20 with the frame 10 is prevented.

According to the semiconductor device in the present disclosure, contact of the deformed metal wire 20 with the frame 10 can be prevented more reliably.

Described in the present embodiment is the configuration that the first non-protruding portion 11a is provided to the first die pad portion 11 and the second non-protruding portion 12a is provided to the second die pad portion 12, that is to say, the non-protruding portion which does not protrude from the semiconductor element in a plan view is provided to both the first die pad portion 11 and the second die pad portion 12. However, as illustrated in FIG. 3, for example, when the second die pad portion 12 is disposed in a lower position than the first die pad portion 11, it is effective to provide the non-protruding portion to the first die pad portion 11 by reason that contact with the metal wire 20 tends to occur in the first die pad portion 11.

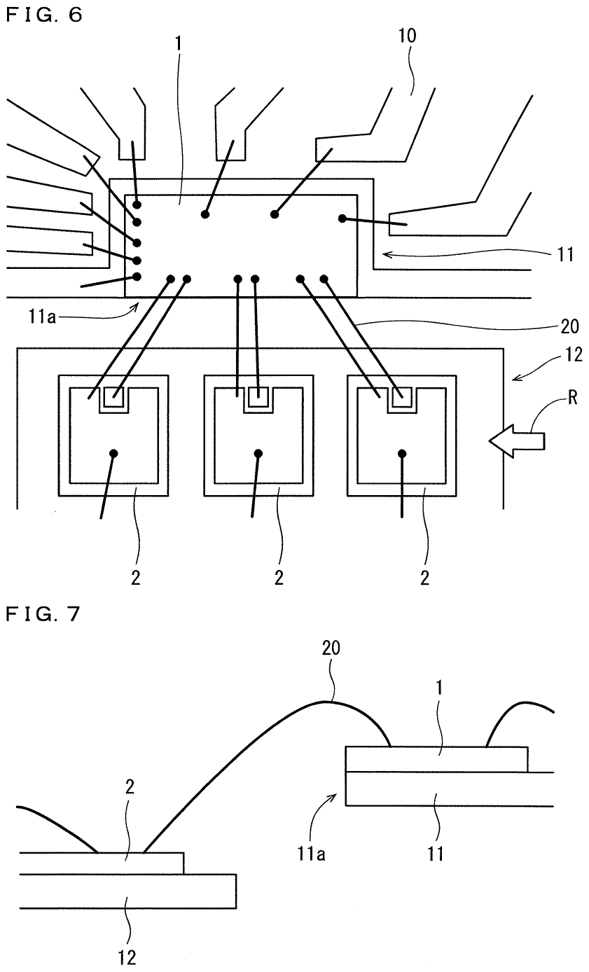

Thus, as illustrated in FIG. 6 and FIG. 7, also applicable is a configuration that the first non-protruding portion 11a is provided to the first die pad portion 11 and the second non-protruding portion 12a is not provided to the second die pad portion 12. That is to say, when a height is different between the first die pad portion 11 and the second die pad portion 12, the non-protruding portion (the first die pad portion 11 or the second die pad portion 12) may be provided to only one thereof having a larger height. There is a possibility that strength of the frame 10 decreases in a position provided with the non-protruding portion. Thus, increase of strength of the frame 10 can be expected by reducing the position provided with the non-protruding portion.

Short circuit of a circuit does not occur in a part of the frame 10 having the same potential as the metal wire 20 such as a part of the frame 10 directly connected to the metal wire 20 even when the metal wire 20 pressed by the resin and deformed has contact with the part thereof. Thus, the non-protruding portion needs not be provided to a region in which the metal wire 20 passes through in a part of the frame 10 having the same potential as the metal wire 20.

### Embodiment 2

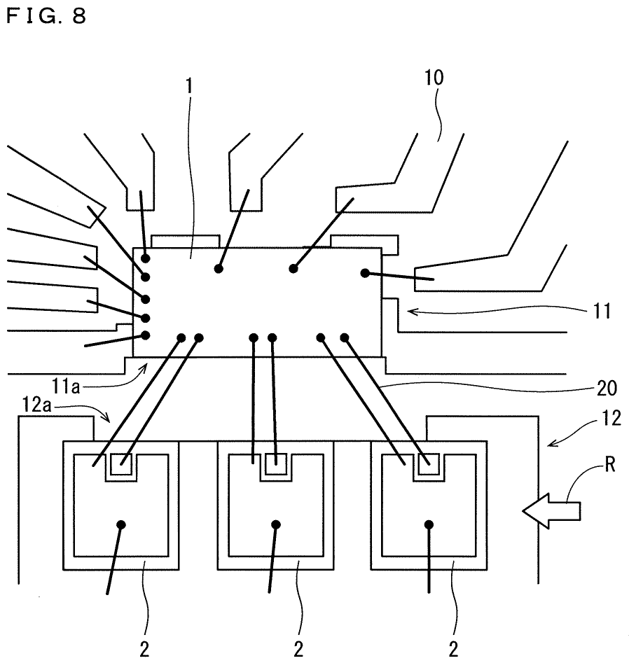

FIG. 8 is a plan view of a main portion (near the first die pad portion 11 and the second die pad portion 12) of a semiconductor device according to an embodiment 2.

In the semiconductor device according to the embodiment 2, the first non-protruding portion 11a and the second non-protruding portion 12a have a notched shape in a plan view. Since the other configuration is similar to that of the embodiment 1, the description thereof is omitted.

When the first non-protruding portion 11a and the second non-protruding portion 12a have the notched shape, a range of the non-protruding portion in the frame 10 is reduced, and increase of strength of the frame 10 can be expected compared with the embodiment 1.

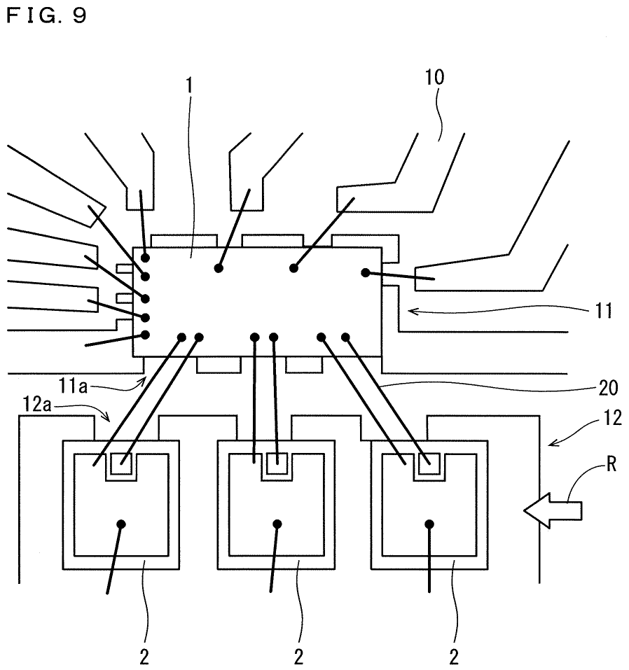

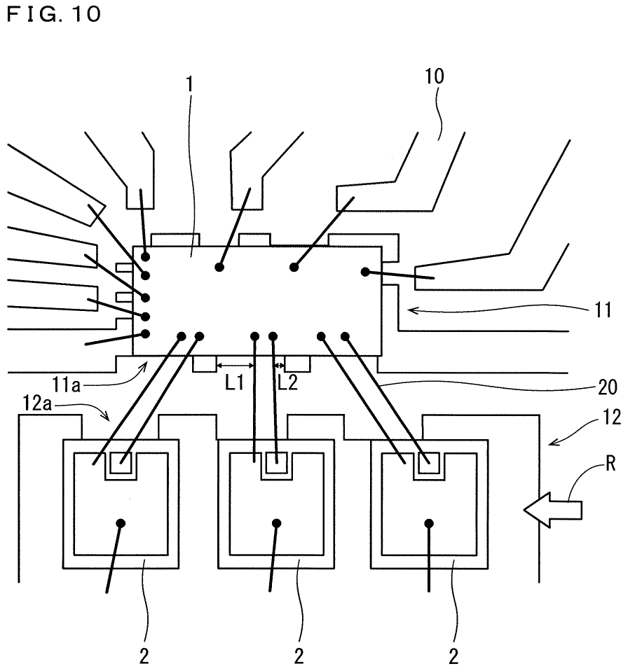

From a viewpoint of increase of strength of the frame 10, the range of providing the non-protruding portion to the frame 10 is preferably smaller. Thus, as illustrated in FIG. 9, for example, the non-protruding portion (the first non-protruding portion 11a or the second non-protruding portion 12a) may be locally provided to a region in which the metal wire 20 passes through in the plan view. In FIG. 9, the number of non-protruding portions increases compared with FIG. 8, but a width of each non-protruding portion is small. Thus, the range of the non-protruding portion is smaller than that in FIG. 8.

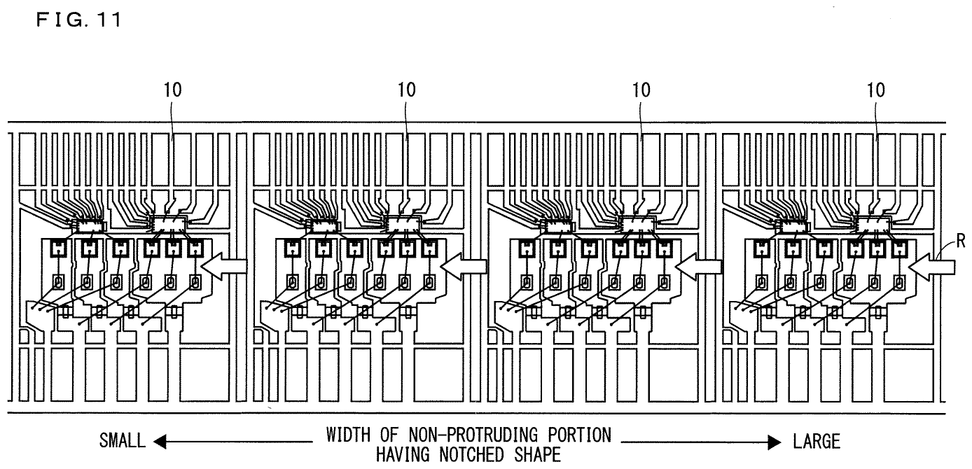

In FIG. 9, the non-protruding portion (the first non-protruding portion 11a or the second non-protruding portion 12a) is disposed so that the metal wire 20 passes through a center part thereof. However, when the non-protruding portion is provided to the side parallel to the resin flowing direction R of the die pad portion (the first die pad portion 11 or the second die pad portion 12), as illustrated in FIG. 10, a distance L1 from an end of the non-protruding portion on a downstream side (a side farther away from the resin injection mark 30a) of the resin flowing direction R to the metal wire 20 is preferably larger than a distance L2 from an end of the non-protruding portion on an upstream side (a side closer to the resin injection mark 30a) of the resin flowing direction R to the metal wire 20. Since the metal wire 20 is deformed to be flowed to the downstream side of the resin flowing direction R, contact of the metal wire 20 with the frame 10 can be effectively prevented when the distance L1 is larger than the distance L2.

The shape of each of the first non-protruding portion 11a and the second non-protruding portion 12a having the notched shape is not limited to that of the example (the shape having right-angled corners) illustrated in FIG. 8 to FIG. 10, but may be a tapered shape, for example.

### Embodiment 3

In manufacturing the semiconductor device according to the embodiments 1 and 2, when a mold which can mold the plural pieces of sealing resin 30 at the same time is used, the plurality of semiconductor devices can be formed at the same time. In this case, the plurality of frames 10 each including the first semiconductor element 1 and the metal wire 20 are disposed side by side in the mold as illustrated in FIG. 11. When the resin is injected from the resin injection inlet of the mold, the plural pieces of sealing resin 30 sealing the plurality of frames 10, respectively, are molded at the same time, and the plurality of semiconductor devices are formed at the same time. However, the plural pieces of sealing resin 30 are connected in the mold. Thus, the plurality of semiconductor devices formed at the same time are taken out from the mold, and then cut into the plurality of semiconductor devices by cutting the sealing resin 30.

Herein, in the process of injecting the resin in the mold, influence of flow of the resin is large in a position near the resin injection inlet of the mold (the upstream side of the resin flowing direction R), and deformation of the metal wire 20 tends to be large. In the meanwhile, influence of flow of the resin is smaller in a position away from the resin injection inlet of the mold (the downstream side of the resin flowing direction R), and deformation of the metal wire 20 tends to be small. Thus, in the embodiment 3, when the plurality of frames 10 are disposed in the mold, as illustrated in FIG. 11, the frame 10 including the non-protruding portion (the first non-protruding portion 11a or the second non-protruding portion 12a) with a small width is disposed in the position away from the resin injection inlet, and the frame 10 including the non-protruding portion with a large width is disposed in the position near the resin injection inlet. That is to say, the width of the non-protruding portion of the frame 10 disposed away from the resin injection inlet is smaller than the width of the non-protruding portion of the frame 10 disposed near the resin injection inlet in the mold.

According to the method of manufacturing the semiconductor device according to the embodiment 3, obtained is the semiconductor device including the frame 10 with large strength (the width of the non-protruding portion is small) at the position away from the resin injection inlet in the mold while preventing contact of the metal wire 20 with the frame 10.

Each embodiment can be arbitrarily combined, or each embodiment can be appropriately varied or omitted.

### APPENDIX

The aspects of the present disclosure are collectively described hereinafter as appendixes.

### Appendix 1

A semiconductor device, comprising:
at least one frame including a first die pad portion including a first semiconductor element;
a metal wire connected to the first semiconductor element; and
sealing resin sealing a part of the frame, the first semiconductor element, and the metal wire, wherein
the first die pad portion includes a first non-protruding portion as a part which does not protrude from the first semiconductor element in a region in which the metal wire passes through in a plan view.

### Appendix 2

The semiconductor device according to Appendix 1, wherein
when a direction perpendicular to a side including a resin injection mark of the sealing resin is a resin flowing direction,
the first non-protruding portion is provided to a side parallel to the resin flowing direction of the first die pad portion in a plan view.

### Appendix 3

The semiconductor device according to Appendix 1, wherein
the first non-protruding portion is provided to a side parallel to a longitudinal direction of the sealing resin in the first die pad portion in a plan view.

### Appendix 4

The semiconductor device according to any one of Appendixes 1 to 3, wherein
the first non-protruding portion has a notched shape in a plan view.

### Appendix 5

The semiconductor device according to Appendix 4, wherein
the first non-protruding portion having the notched shape is locally provided to a region in which the metal wire passes through in the first die pad portion in a plan view.

### Appendix 6

The semiconductor device according to Appendix 4 or 5, wherein
when a direction perpendicular to a side including a resin injection mark of the sealing resin is a resin flowing direction,
the first non-protruding portion is provided to a side parallel to the resin flowing direction of the first die pad portion in a plan view, and
a distance from an end of the first non-protruding portion on a downstream side of the resin flowing direction to the metal wire is larger than a distance from an end of the first non-protruding portion on an upstream side of the resin flowing direction to the metal wire.

### Appendix 7

The semiconductor device according to any one of Appendixes 1 to 6, wherein
the frame further includes a second die pad portion including a second semiconductor element connected to the first semiconductor element via the metal wire and disposed in a lower position than the first die pad portion.

### Appendix 8

The semiconductor device according to Appendix 7, wherein
the second die pad portion includes a second non-protruding portion as a part which does not protrude from the second semiconductor element in at least a part of a region in which the metal wire passes through in a plan view.

### Appendix 9

A method of manufacturing the semiconductor device according to any one of Appendixes 4 to 6, comprising steps of:
locating the plurality of frames each including the first semiconductor element and the metal wire side by side in a mold;
injecting resin from a resin injection inlet of the mold to form the sealing resin; and
cutting the sealing resin to make a plurality of the semiconductor devices, wherein
a width of the first non-protruding portion of the frame disposed farther away from a resin injection inlet of the mold is smaller than a width of the first non-protruding portion of the frame disposed closer to the resin injection inlet.

While the disclosure has been shown and described in detail, the foregoing description is in all aspects illustrative and not restrictive. It is therefore understood that numerous modifications and variations can be devised.

What is claimed is:

1. A semiconductor device, comprising:
at least one frame including a first die pad portion including a first semiconductor element;
a metal wire connected to the first semiconductor element; and
sealing resin sealing a part of the frame, the first semiconductor element, and the metal wire, wherein
the first die pad portion includes a first non-protruding portion as a part which does not protrude from the first semiconductor element in a region in which the metal wire passes through in a plan view.

2. The semiconductor device according to claim 1, wherein
when a direction perpendicular to a side including a resin injection mark of the sealing resin is a resin flowing direction,
the first non-protruding portion is provided to a side parallel to the resin flowing direction of the first die pad portion in a plan view.

3. The semiconductor device according to claim 1, wherein
the first non-protruding portion is provided to a side parallel to a longitudinal direction of the sealing resin in the first die pad portion in a plan view.

4. The semiconductor device according to claim 1, wherein
the first non-protruding portion has a notched shape in a plan view.

5. The semiconductor device according to claim 4, wherein
the first non-protruding portion having the notched shape is locally provided to a region in which the metal wire passes through in the first die pad portion in a plan view.

6. The semiconductor device according to claim 4, wherein
when a direction perpendicular to a side including a resin injection mark of the sealing resin is a resin flowing direction,
the first non-protruding portion is provided to a side parallel to the resin flowing direction of the first die pad portion in a plan view, and
a distance from an end of the first non-protruding portion on a downstream side of the resin flowing direction to the metal wire is larger than a distance from an end of the first non-protruding portion on an upstream side of the resin flowing direction to the metal wire.

7. The semiconductor device according to claim 1, wherein
the frame further includes a second die pad portion including a second semiconductor element connected to the first semiconductor element via the metal wire and disposed in a lower position than the first die pad portion.

8. The semiconductor device according to claim 7, wherein
the second die pad portion includes a second non-protruding portion as a part which does not protrude from the second semiconductor element in at least a part of a region in which the metal wire passes through in a plan view.

9. A method of manufacturing the semiconductor device according to

4. comprising steps of:
locating the plurality of frames each including the first semiconductor element and the metal wire side by side in a mold;
injecting resin from a resin injection inlet of the mold to form the sealing resin; and
cutting the sealing resin to make a plurality of the semiconductor devices, wherein
a width of the first non-protruding portion of the frame disposed farther away from the resin injection inlet of the mold is smaller than a width of the first non-protruding portion of the frame disposed closer to the resin injection inlet.
